(19) United States
(12) Patent Application Publication
(10) Pub. No.: US 2007/0058686 A1
(43) Pub. Date: Mar. 15, 2007

(54) ACTIVE OPTICAL ANTENNA

(76) Inventors: Federico Capasso, Cambridge, MA (US); Ken Crozier, Cambridge, MA (US); Ertugrul Cubukcu, Cambridge, MA (US); Eric Kort, Cambridge, MA (US); Nanfang Yu, Chengdu (CN); Elizabeth Smythe, Cambridge, MA (US)

Correspondence Address: 24IP LAW GROUP USA, PLLC, 12 E. LAKE DRIVE, ANNAPOLIS, MD, 21403, US

(21) Appl. No.: 11/464,758

(22) Filed: Aug. 15, 2006

Related U.S. Application Data
(60) Provisional application No. 60/708,659, filed on Aug. 16, 2005.
(60) Provisional application No. 60/753,704, filed on Dec. 24, 2005.

(51) Int. Cl. H01S 5/00; H04B 10/00

(52) U.S. Cl. 372/43.01; 398/116

(57) ABSTRACT

A new class of photonic devices called active optical antennas, which consist of metallic structures directly integrated on to the facet of a semiconductor lasers, and of instruments based on such antennas are disclosed. The structures consist of metallic elements which function as antennas at optical wavelengths by spatially concentrating laser radiation of wavelength in the range from the UV to the mid-infrared into spots (with sizes in the range 10-100 nm) in the so called near field zone, that is at subwavelength distances from the facet. Various antenna designs are considered depending on the laser under consideration and applications. This invention has wide ranging applications such as new microscopes for high-resolution spatially resolved imaging and spectroscopy, new probes for biology, laser assisted processing and repair of devices, circuits and masks, as well new optical tweezers and phased array devices. Microscopes and other systems based on this invention are discussed. Further, a number of inventions relating to optical antennas and of instruments based on such antennas are disclosed. An important technology consisting of optical antennas fabricated at the ends of optical fibers is disclosed. A technique for imaging the field distributions on active optical antennas is disclosed. New designs of optical antennas are disclosed. Applications of optical antennas in microfluidic systems are disclosed.

### CROSS-REFERENCE TO RELATED APPLICATIONS

The present application claims the benefit of the filing dates of U.S. Provisional Application Ser. No. 60/708,659 entitled “Active Optical Antennas” and filed on Aug. 16, 2005 and U.S. Provisional Application Ser. No. 60/753,704 entitled “Active Optical Antenna” and filed on Dec. 24, 2005.

The above cross-referenced related applications are hereby incorporated by reference herein in their entirety.

### STATEMENT REGARDING FEDERALLY SPONSORED RESEARCH OR DEVELOPMENT

None.

### BACKGROUND OF THE INVENTION

1. Field Of The Invention

The present invention relates to a new class of photonic devices referred to as active optical antennas and instrumentation incorporating such devices.

2. Brief Description Of The Related Art

To achieve below diffraction limit resolution, the Near Field Scanning Optical Microscope, which uses subwavelength apertures in metals, has become a tool of choice to produce optical spots of nanometric dimensions (See E. Betzig and J. K. Trautman, Science 257, 189 (1992)). This technique suffers however from limited optical throughput, which limits the range of applications. This problem has been partially alleviated through the use of so called solid immersion lenses (See M. Mansfield and G. S. Kino, Appl. Phys. Lett. 57, pp. 2615 (1990) and K. B. Crozier et al, Journal of Microelectromechanical Systems 11, pp. 470 (2002))

An alternative approach is to scatter instead the incident light with a so-called optical antenna of subwavelength dimensions, which enhances the near field intensity by many orders of magnitude compared to NSOMs (See K. B. Crozier et al, Journal of Applied Physics 94, pp. 4632 (2003)) Physically in an optical antenna the incident light is coupled into surface plasmon (SP) modes. These are surface optical waves coupled to collective charge oscillations in the metal, known as plasmons. The SPs have wavelengths well below that of light in free space due to their large effective refractive index. As a result light gets concentrated and is re-radiated into the near field down to dimensions in the 10-100 nm range.

Surface plasmons are collective excitations of the electron plasma in a metal by electromagnetic radiation. (See S. A. Maier and H. Atwater, J. Appl. Phys. 98, 1 (2005) and A. V. Zayats, I. I. Smolyaninov, A. A. Maradudin, Physics Rep. 408, 131 (2005)) They have been extensively used in various applications ranging from biosensors to near field optical microscopes and devices. Early applications such as surface plasmon microscopy such as is described in B. Rothenhausler and W. Knoll, Nature 332, 615 (1988), some of which have achieved single atomic layer sensitivity (see A. N. Grigorenko, P. I. Nikitin, and A. V. Kabashin, Appl. Phys. Lett. 75, 3917 (1999), made use of plasmon excitation in thin metal films.

With the currently available nanofabrication techniques such as electron beam lithography and focused ion beam (FIB) milling, it has become possible to exploit plasmon resonances in coupled metallic nanoparticles, including periodic arrays. Experiments have demonstrated a large optical near-field enhancement around such nanoparticles, which is important for surface spectroscopic techniques such as surface enhanced Raman spectroscopy (SERS). (See S. Nie and S. R. Emory, Science 275, 1102 (1997)).

Optical antennas are single or coupled metallic nanoparticles in which optical excitation of surface plasmons can produce very high intensities in the optical near field due to the high curvature of the metal surfaces. The field enhancement relative to the incident field is maximum when the wavelength is suitably matched to the size of the nanoparticle (resonant optical antenna). Optical antennas were first demonstrated at microwave frequencies and more recently at mid-infrared and near infrared frequencies (See P. J. Schuck, D. P. Fromm, A. Sundaramurthy, G. S. Kino, and W. E. Moemer, Phys. Rev. Lett. 94, 017402 (2005); P. Muhlschlegel, H. J. Eisler, O. J. F. Martin, B. Hecht, and D. W. Pohl, Science 308, 1607 (2005); and J. N. Farahani, D. W. Pohl, H. J. Eisler, and B. Hecht, Phys. Rev. Lett. 95, 017402 (2005). Of particular interest are resonant optical antennas comprising a pair of strongly coupled metallic nanorods. This design leads to a large intensity enhancement localized in the gap between the latter.

U.S. Patent Publication No. US2001/0009541, published on Jul. 26, 2001, discloses a system in which “a laser beam emitted from a semiconductor laser enters an incident surface of a transparent condensing medium with a central part of the laser beam being shielded by a shading metal member, and a light spot is formed on a light-condensed surface of the transparent condensing medium. When this light spot is applied to a micro metal member, plasmon of the micro metal member is excited, and near field light leaks out there from. The near field light enters a recording medium of a disk as propagation light, and recording into and reproduction from the recording medium is performed by this light.”

The enhanced transmission of light through sub-wavelength apertures and aperture arrays in metal films, a phenomenon associated with surface plasmons, has also attracted considerable interest. (See T. W. Ebbesen, H. J. Lezec, H. F. Ghaemi, T. Thio, and P. A. Wolff, Nature 391, 667 (1998)). Very small aperture lasers that consist of a laser diode with its facet coated by a metal film on which a sub-wavelength aperture such as a circular hole or a C-aperture is etched by FIB milling, have been demonstrated. (See A. Partovi, D. Peale, M. Wuttig, C. A. Murray, G. Zydzik, L. Hopkins, K. Baldwin, W. S. Hobson, J. Wynn, J. Lopata, L. Dhar, R. Chichester, and J. H. Yeh, Appl. Phys. Lett. 75, 1515 (1999); F. Chen, A. Itagi, J. A. Bain, D. D. Stancil, T. E. Schlesinger, L. Stebounova, G. C. Walker, and B. B. Akhremitchev, Appl. Phys. Lett. 83, 3245 (2003); and U.S. Patent Publication No. US2005/0030993 A1). However, these devices suffer from limited output power even though the transmission is enhanced when normalized to the aperture area.

### SUMMARY OF THE INVENTION

A new class of photonic devices called active optical antennas, which consist of metallic structures directly integrated onto the facet of a semiconductor laser, and of instruments based on such antennas is disclosed. The structures consist of metallic elements which function as antennas at optical wavelengths by spatially concentrating laser radiation of wavelength in the range from the UV to the mid-infrared into spots (with sizes in the range 10-100 nm) in the so called near field zone, that is at subwavelength distances from the facet. Various antenna designs are considered depending on the laser under consideration and applications.

This invention has wide ranging applications such as new microscopes for high-resolution spatially resolved imaging and spectroscopy, new probes for biology, laser assisted processing and repair of devices, circuits and masks, as well new optical tweezers and phased array devices. Microscopes and other systems based on this invention are discussed.

In a preferred embodiment, the present invention is a semiconductor laser apparatus that comprises an active region, a laser facet and an optical antenna on said laser facet. The optical antenna may take any of a number of forms, including but not limited to a bow tie antenna, a dipolar optical antenna, and a cross optical antenna. The active optical antenna further could be formed in an opening in a metal coating on the facet of the laser. The semiconductor laser could, for example, be a diode laser or a quantum cascade laser.

In another preferred embodiment, the present invention is a semiconductor laser apparatus that comprises an active region, a facet and a metallic structure integrated on the facet of the semiconductor laser. The metallic structure may comprise metallic elements functioning as antennas at optical wavelengths by spatially concentrating laser radiation of wavelength in the near field zone.

In still another embodiment, the present invention is a laser apparatus that comprises a laser, an optical fiber coupled to the laser where the optical fiber has a facet and an optical antenna is formed on the facet of the optical fiber. The optical antenna may comprise, for example, an array of metallic nanorods, a bow tie antenna, a cross optical antenna, or a dipolar optical antenna. The optical antenna also may comprise a metal coating having an opening therein or may comprise an array of optical antennas.

In yet another embodiment, the present invention is a laser apparatus that comprises a fiber laser having a facet and an optical antenna on said facet of said fiber laser. In still other embodiments, the present invention is an instrument such as an optical storage device, an NSOM for imaging or chemical analysis, a mask, or a device for IC repair.

In another embodiment, the present invention is a laser apparatus that comprises a fiber laser amplifier having a facet and an optical antenna on the facet. The optical antenna may comprise an array of optical antennas.

Still other aspects, features, and advantages of the present invention are readily apparent from the following detailed description, simply by illustrating a preferable embodiments and implementations. The present invention is also capable of other and different embodiments and its several details can be modified in various obvious respects, all without departing from the spirit and scope of the present invention.

Accordingly, the drawings and descriptions are to be regarded as illustrative in nature, and not as restrictive. Additional objects and advantages of the invention will be set forth in part in the description which follows and in part will be obvious from the description, or may be learned by practice of the invention.

### BRIEF DESCRITION OF THE DRAWINGS

For a more complete understanding of the present invention and the advantages thereof, reference is now made to the following description and the accompanying drawings, in which:

FIG. 1 is a diagram of an edge-emitting laser in accordance with a preferred embodiment of the present invention.

FIG. 2 is a diagram of an edge-emitting laser in accordance with a preferred embodiment of the invention.

FIG. 3 illustrates an electric field intensity enhancement in a resonant dipole antenna in accordance with a preferred embodiment of the invention.

FIG. 4 is a diagram of an active optical antenna optimized for quantum cascade lasers in accordance with a preferred embodiment of the invention.

FIG. 5 is a diagram of an active optical antenna optimized for quantum cascade lasers in accordance with a preferred embodiment of the invention.

FIG. 6 is a diagram of a system in accordance with a preferred embodiment of the invention.

FIG. 7 is a diagram of an optical antenna in accordance with a preferred embodiment of the invention.

FIG. 8 is a diagram of an optical antenna in accordance with another preferred embodiment of the present invention.

FIG. 9 is a diagram of a preferred embodiment of an optical antenna fabricated at the end of an optical fiber in accordance with the present invention.

FIGS. 10(a)-(c) are alternative designs for embodiments of optical antennas at the end of optical fibers in accordance with the present invention. FIG. 10(a) is a cross optical antenna in accordance with an embodiment of the present invention. In FIG. 10(b), the end of an optical fiber is coated with metal, except that it contains an opening in which a dipole optical antenna is fabricated, in accordance with an embodiment of the present invention. FIG. 10(c) illustrates a cross optical antenna fabricated in metal opening in accordance with an embodiment of the present invention.

FIG. 11 is a diagram of an embodiment of an optical antenna fabricated at the end of a fiber laser in accordance with the present invention.

FIG. 12 is a top view of optical antennas integrated into a microfluidic system in accordance with a preferred embodiment of the present invention.

FIG. 13(a) is a scanning electron microscope image of a structure fabricated in accordance with a preferred embodiment of the present invention.

FIG. 13(b) is an FDTD simulation of electric filed intensity (<″E″2>) distribution on an optical antenna in accordance with an embodiment of the present invention, normalized to electric field intensity of illuminating plane wave. Electric field (E) and propagation vector (k) of illuminating plane wave are shown.

FIG. 14(a) is a diagram of measurement of field distribution on optical antenna with scattering-type apertureless scanning near-field optical microscope. EL—optical field on photodiode from laser diode output. ES—optical field on photodiode resulting from sharp AFM tip scattering fields on surface of an optical antenna in accordance with a preferred embodiment of the present invention.

FIG. 14(b) is a graph of intensity distribution along the dashed line in FIG. 10(c).

FIG. 14(c) is an image of a measured optical near field intensity distribution of the antenna structure with 2 f detection. The color scale is in arbitrary units.

FIG. 15(a) is a diagram of a scanning electron micrograph of a resonant optical antenna in accordance with a preferred embodiment of the present invention.

FIG. 15(b) is a numerical simulation of the total electric field intensity enhancement with respect to the incident intensity in a preferred embodiment of the invention. The enhancement reaches values ˜800 near the middle of the gap.

FIG. 16(a) is an AFM topography of a preferred embodiment of the present invention.

FIG. 16(b) is an a-NSOM image of a resonant optical antenna in accordance with a preferred embodiment of the present invention fabricated on one of the facets of a commercial diode laser operating at ˜0.83 μm wavelength.

FIG. 16(c) is a line-scan of the near-field distribution along the antenna axis for a preferred embodiment of the present invention.

FIG. 17 is a diagram illustrating a fiber having arrays of metallic nanorods on the facet of the fiber in accordance with a preferred embodiment of the present invention.

FIGS. 18(a)-(c) are diagrams illustrating rod spacing in various embodiments of the present invention.

FIG. 19 is a graph illustrating the effects of changes in array spacing and coupling in an array of antennas in accordance with the present invention.

FIG. 20 is a diagram illustrating the effects of array spacing and coupling in an array of antennas in accordance with a preferred embodiment of the present invention.

FIG. 21 illustrates spectral responses to changes in surrounding media in accordance with the present invention.

### DETAILED DESCRIPTION OF THE PREFERRED EMBODIMENTS

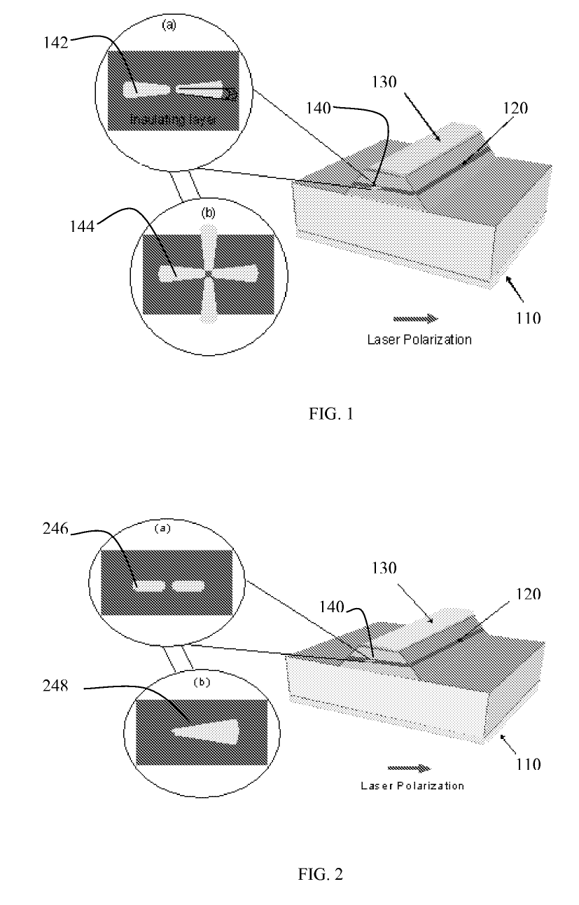

In a preferred embodiment, the present invention is a generic semiconductor laser in which an optical antenna has been monolithically integrated onto the laser facet. The laser is typically an edge emitting laser (FIGS. 1 and 2) with wavelengths in the range from the blue/uv (Gallium Indium Nitride based lasers) to the near infrared (GaAs and InP based lasers) and the mid-infrared ( Antimony based). It could, for example, either be a diode laser or a quantum cascade laser. However vertical cavity surface emitting lasers with optical antennas defined onto the top-emitting surface can also be implemented.

Previously very small metallic aperture lasers (VSALs) with subwavelength metallic apertures defined on their facet have been implemented for possible applications in optical recording but have suffered from the same limitation of NSOMs. (See A. Partovi, et al. Appl. Phys. Lett. 75, 1515 (1999) and Qiaoquan Gan et al. Optics Lett. 30, 1470 (2005)).

As shown in FIG. 1, such a semiconductor laser may have a back contact 110, an active region 120 and a top contact 130. An active optical antenna 140 is located on the facet of the laser. One implementation of the invention uses a bowtie antenna 142 of length comparable to the SP wavelength, aligned along the direction along the laser polarization. It is shown as inset (a) of FIG. 1 for a laser diode with polarization in the plane of the active region 120 (TE polarization). This allows a strong concentration of the electric field in the gap of the antenna.

Inset (b) of FIG. (1) shows a cross optical antenna 144 that will produce even higher intensities due to its better coupling to the near field, which has polarization components along directions parallel and perpendicular to the active region 130 as well as normal to the facet.

FIG. 2 shows a slight modification (a) of the bow-tie design, referred to as a dipolar optical antenna 246, while (b) shows a single element half-wave antenna 248. Although it will give smaller field enhancement than the bow-tie design, its simplicity of fabrication might be advantageous for certain uses.

It is worth mentioning that all antennas may be fabricated on a thin dielectric layer (e.g. silicon dioxide or silicon nitride) directly deposited on the facet by standard methods in order to avoid electrical shorting of the laser.

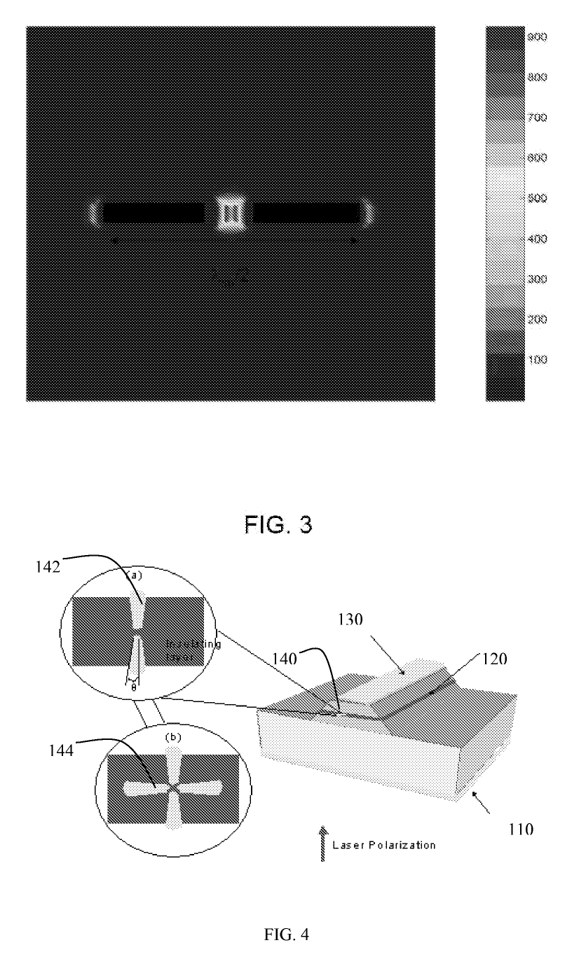

In simulations of a dipolar optical antenna of the type shown in FIG. 2(a) with a length substantially equal to half the SP wavelength. Our calculations (FIG. 3) show a 3 orders of magnitude enhancement (relative to the incident light) in the electric field intensity (i.e. the electric field squared) within the gap due to the resonant nature of the surface-plasmon optical antenna.

If used as an optical active read/write head, the size of the spot is determined by the size of the gap. As opposed to VSALs with an aperture of the same size as the gap, the optical throughput can be large enough (several mW) to burn bits on digital media (e.g. high capacity optical discs). Similarly, this active SP-optical antenna can be used as a near-field scanning optical probe with very high resolution and throughput simply by monitoring the changes in the I-V characteristics. For wavelength in the near infrared the total length L of the antenna will be in the 250-300 nm range, while the gap will be 10-100 nm wide.

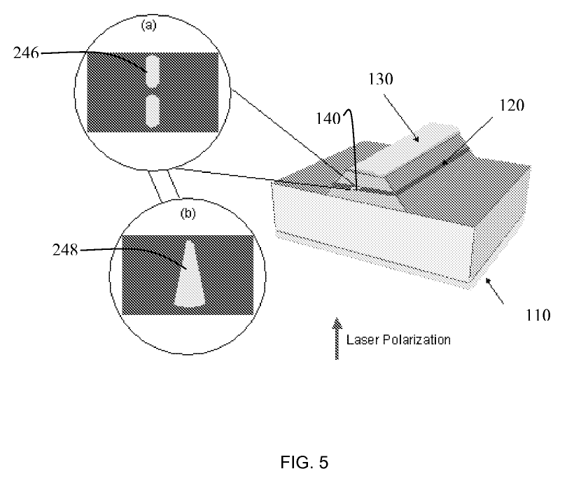

FIGS. 4 and 5 show designs similar to those of FIGS. 1 and 2 but optimized for quantum cascade lasers, which are polarized normal to the active region layers (TM polarization). Here the gap size in (a) is ˜10-100 nm, and the length of the resonant structure is 2.3 micron for a 7 micron wavelength device.

Instruments Based on Active Optical Antennas

A variety of instruments may be based upon the use of active optical antennas in accordance with the present invention. Such instruments include but are not limited to microscopes, laser processing instruments, heads for optical recording and data storage, lithographic instruments, and optical tweezers. The present invention further may be used in new photonic devices.

1. Microscopes

The proposed device offers significantly improved spatial resolution for microscopy, as the resolution is defined by the geometry of the antenna structure, rather than by the wavelength of light. Of particular importance are applications in fluorescence microscopy, enhanced Raman spectroscopy and absorption microscopy.

In fluorescence microscopy, the proposed optical antenna device could be used for microscopy of fluorescently-tagged biomolecules. The advantage of the optical antenna approach lies in its high spatial resolution. This allows it to resolve features spaced much closer together than the wavelength of light. Applications include microscopy of cell membranes, and DNA chips.

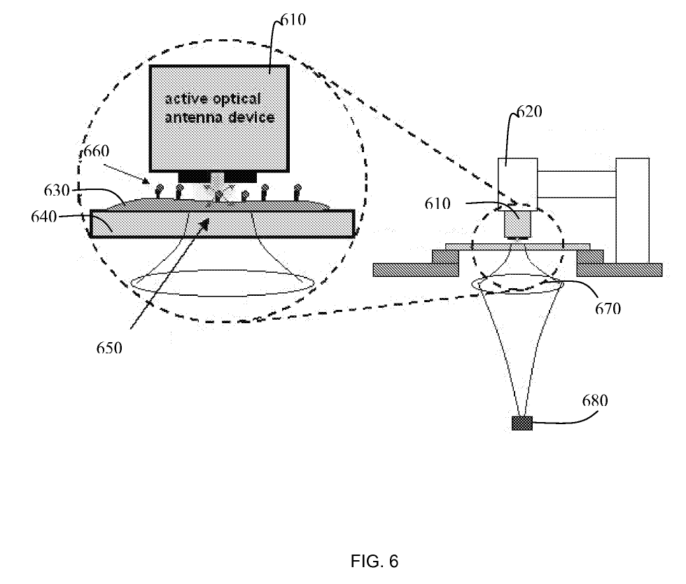

An example system is illustrated in FIG. 6. The active optical antenna generates an intense spatially confined field. The optical antenna device 610 is mounted on a scan head 620, allowing it to be positioned above the sample 630 under study on a quartz coverslip 640. The intense optical fields then excite fluorescent emission 650 from the fluorophores 660 on the surface of the sample 630, which is then collected by a lens 670 onto a detector 680. The sample is scanned in x and y, and a fluorescence image is built up of the sample by recording the detector signal as a function of position. It should be noted that the spatial resolution will be given by the spatial confinement of the fields in the gap of the antenna, which could be on the order of 10 nm.

In enhanced Raman spectroscopy, the optical antenna approach could overcome the key challenge facing this technique: the Raman scattering signals are very weak due to the fact that Raman scattering cross sections are very small. The proposed device could be used for Raman microscopy of biological samples, and also for integrated-circuit fabrication. In IC fabrication, the device would be useful for strain mapping of IC devices, which would be important for failure analysis. It could also be useful for identifying impurities resulting from different steps in the fabrication process.

The proposed device would also be very useful at mid-infrared wavelengths for absorption microscopy. In particular, it could be used for spatially-resolved measurements on proteins. The optical antenna would therefore be an alternative to synchrotron radiation, but would be substantially more compact.

2. Laser Processing Instruments

An important technological application of lasers is for materials processing. Annealing, mask repair and IC defect repair are important examples of lasers in IC fabrication. In these examples, there is a great need to improve spatial resolution due to the continual progression of the semiconductor industry to smaller feature sizes. The optical antenna could therefore be very useful for these applications due to the improved spatial resolution it offers.

3. Write Heads for Optical Recording and Data Storage

Optical data storage using writable CDs and DVDs is a popular means for data storage for personal computers and compact disc players, but the storage density is limited by the resolution limit of conventional optics. The optical antenna offers a substantial improvement in spatial resolution, which in turn leads to increased storage density.

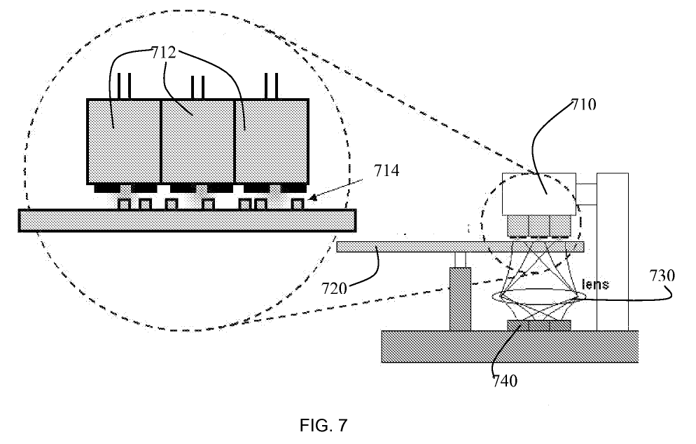

An example system is shown as FIG. 7. The system consists of an array of optical antennas 712 incorporated into an optical read head 710, positioned over a spinning optical disk 720. Each active optical antenna 712 generates an intense and spatially confined field. A bit on the optical disk scatters the field from the antenna, with the scattered light being collected by a lens 730 onto a photodetector array 740. Because of the spatial confinement of the optical field from the optical antenna to dimensions of ˜10 nm, a bit with comparable dimensions will give an appreciable signal at the detector.

4. Lithographic Instrumentation

The semiconductor industry is continually decreasing the feature sizes in integrated circuits to improve device performance and density. This has been largely achieved by improvements in lithography through the use of shorter wavelengths. The optical antenna offers a spatial resolution considerably better than that of conventional optical systems. However, it must be noted that the optical antenna is a serial device, in which a region of focused optical energy must be scanned over the sample to image or modify it. In lithography, the writing speed is of key importance, as it determines the fabrication cost. However, serial approaches are also very important in IC fabrication. In mask making, electron beam lithography is often used. The optical antenna could be of great use in such applications in which the lithography is done in a serial fashion. In addition, it would be possible to manufacture write heads, incorporating 1D or 2D arrays of antennas. The optical antenna has a footprint equal to that of a semiconductor laser, meaning that it is small enough to be integrated into parallel arrays, with tens or possibly hundreds of devices operating at once.

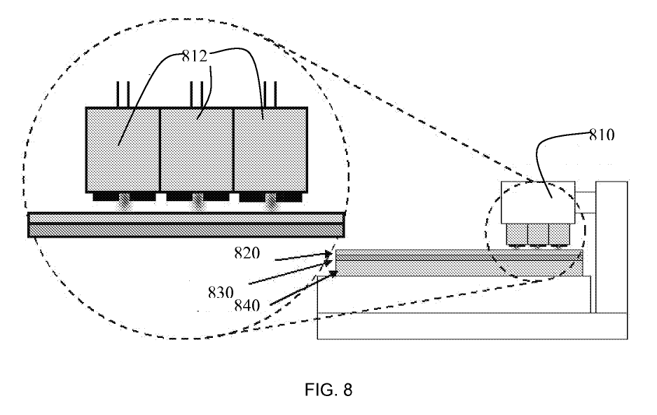

An example system is shown as FIG. 8. In this system, an array of optical antennas 812 is incorporated into a scan head 810. Each element of the array generates an intense and spatially confined field that can be used to expose photoresist 820 on the mask 840, with chrome layer 830 interposed between the photoresist 820 and the mask 840. The head 810 is scanned across the mask 840, and the light output from each antenna element 812 is modulated to expose the desired pattern in the photoresist 820.

5. Optical Tweezers

Optical tweezers use light to manipulate microscopic objects as small as a single atom. The radiation pressure from a focused laser beam is able to trap small particles. They find great use in the biological sciences, where they are used to apply forces in the pN-range and to measure displacements in the nm range of objects ranging in size from 10 nm to over 100 microns. The intense and spatially confined fields produced by the optical antenna could be used for the trapping and manipulation of small particles for biology.

6. New Photonic Devices Based on Optical Antenna

Optical antennas also open up new possibilities for photonic devices. The underlying concept is that the antenna improves the match between light (with spatial dimension on the scale of the wavelength, e.g. 500 nm) and objects such as quantum dots (with spatial dimensions on the 1-10 nm scale). One example application consists of an optical antenna with a quantum dot positioned in the antenna gap. In the antenna gap, the optical fields are intense and spatially localized. Therefore, the antenna provides a means to improve the efficiency of illuminating the quantum dot. The quantum dot would emit at a wavelength different from that of the laser diode. Therefore, the optical antenna provides a means for efficient frequency conversion. It should also be noted that in certain applications, multiple antennas would be fabricated on the laser diode facet to modify the far-field beam. In antenna engineering, this configuration is referred to as a phased array.

Advantages of Integrating the Optical Antenna on a Laser Diode

In a preferred embodiment, the present invention is incorporated in a new surface plasmon device that is comprised of a resonant optical antenna integrated on to the facet of a commercial diode laser, termed a plasmonic laser antenna. This device allows intense and spatially confined optical fields to be generated in the near-field zone. Spot sizes of a few tens of nanometers have been measured at a wavelength ˜0.8 μm. This device can be implemented in a wide variety of semiconductor lasers emitting in spectral regions ranging from the visible and the near infrared to the mid- and far-infrared, including quantum cascade lasers. As such it is potentially useful in a broad range of applications including near-field optical microscopes, optical data storage, spatially resolved chemical imaging and spectroscopy and heat-assisted magnetic recording.

The integration of the optical antenna onto the facet of the semiconductor laser offers a number of advantages over the discrete approach. In the discrete approach, the optical antenna is a separate device, and optics (i.e. lenses, mirrors, optical fibers) are used to illuminate it. In this section, advantages of the monolithic, integrated device are outlined.

(1). Fewer Components.

In the integrated approach, the optics used to illuminate the optical antenna is no longer necessary. This has the advantages that the system is much simpler, and that the cost of the device is considerably reduced. Alignment of the laser with the antenna is done during fabrication, thus there is no need to align it during use. There is improved coupling efficiency because there are no losses (e.g. absorption, reflection) from intermediate optics between the laser and the antenna. The combination of the laser, antenna, and photodiode results in a highly compact near-field source with integrated detection. In addition, the packaging cost is much lower, as there is no need for careful alignment of the laser, optics and antenna.

(2). Smaller Footprint

In the discrete approach, most of the volume of the system is taken up by the optics used for illuminating the antenna structure. Though the antenna and the semiconductor laser are the most important parts of the system, they are actually very small in comparison to the rest of the system. In the integrated approach, the device becomes much more compact. In fact, the total size of the system is basically that of the laser diode itself. The smaller footprint is particularly useful because it allows the optical antennas to be made in ID and 2D arrays in “write heads”, leading to a substantial increase in throughput.

(3). Signal to Noise Ratio (SNR)

The integrated approach offers improved signal to noise ratio. The signal levels are higher because the optical antenna is directly illuminated by the semiconductor laser thus avoiding losses from intermediate optics due to limited angular acceptance, misalignment, reflection and scattering. In addition, the noise levels are lower. In the discrete approach, background is generated by the intermediate optics through scattering and processes such as fluorescence. These sources of noise are not present in the integrated approach.

(4). Imaging the Sample by Measuring the Input Impedance of the Laser Diode

The integrated approach also offers an additional imaging mechanism, due the fact that in this configuration, the operation of the semiconductor laser is influenced by the antenna. In the integrated approach, the fields radiated by the antenna are coupled back into the laser. The current-voltage characteristics of the laser are modified by the how much power the antenna radiates back into the laser. This depends on the properties of the sample that is being measured by the antenna. For example, if the sample is very lossy, then the antenna will not radiate much energy back into the laser, as a large fraction of the energy coupled into the antenna is dissipated in the sample. Therefore, by monitoring the input impedance to the antenna as it is scanned over a sample, an image of the sample may be obtained. This imaging mode is not available with the discrete approach.

(5). Amplification of Raman Signals by Laser

In the integrated approach, it is possible to collect a significant fraction of the Raman photons emitted by the sample back into the laser diode. This opens up the opportunity of using the gain medium of the laser to amplify these signals. This would be a solution to the low signal problem of Raman spectroscopy. In optical communications, semiconductor optical amplifiers (SOA) are used to amplify signals. In a similar manner, our device would be used to amplify the Raman photons emitted by the sample.

Optical Antennas Fabricated on the Ends of Optical Fibers

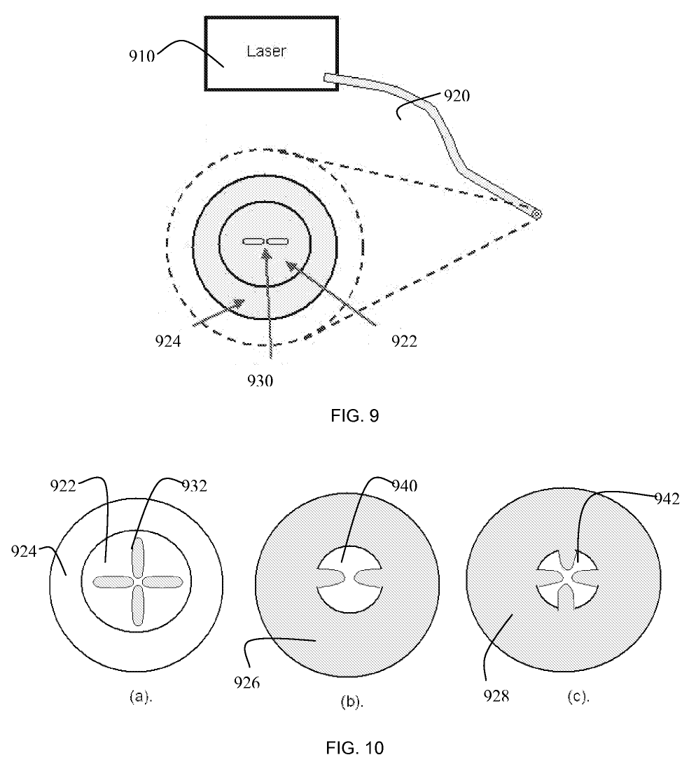

In another preferred embodiment of the present invention, an optical antenna is fabricated at the end of an optical fiber 920, as illustrated in FIG. 9. The laser 910 is coupled into an optical fiber 920, illuminating the optical antenna 930 at the end of the fiber 920. This excites the surface plasmon resonance of the optical antenna 930, which is accompanied by strongly enhanced fields in the gap of the antenna. FIG. 9 shows an antenna consisting of two metal sections separated by a small gap. This is referred to as a dipolar optical antenna. Alternatively, an array of coupled antennas may be designed and used.

In FIG. 10, a number of alternative designs of optical antennas are presented. In FIG. 10(a), a cross optical antenna 932 is shown. In FIGS. 10(b) and (c), another type of optical antenna is shown in which the end of the fiber 920 is fully coated with metal 926, except for an opening 940. In FIG. 10(b), a dipolar optical antenna is formed in the opening 940. In FIG. 10(c), a cross antenna is formed in the opening 942 in metal coating 928. The advantage of the approach of FIGS. 10(b) and (c) is that, by coating the end of the fiber with metal, background light is suppressed.

It is important to note that the optical antenna designs of FIGS. 10(a), (b) and (c) are not restricted to optical antennas fabricated at the ends of optical fibers. These antennas designs could also be fabricated on the facets of semiconductor lasers, on transparent substrates, on AFM tips, etc.

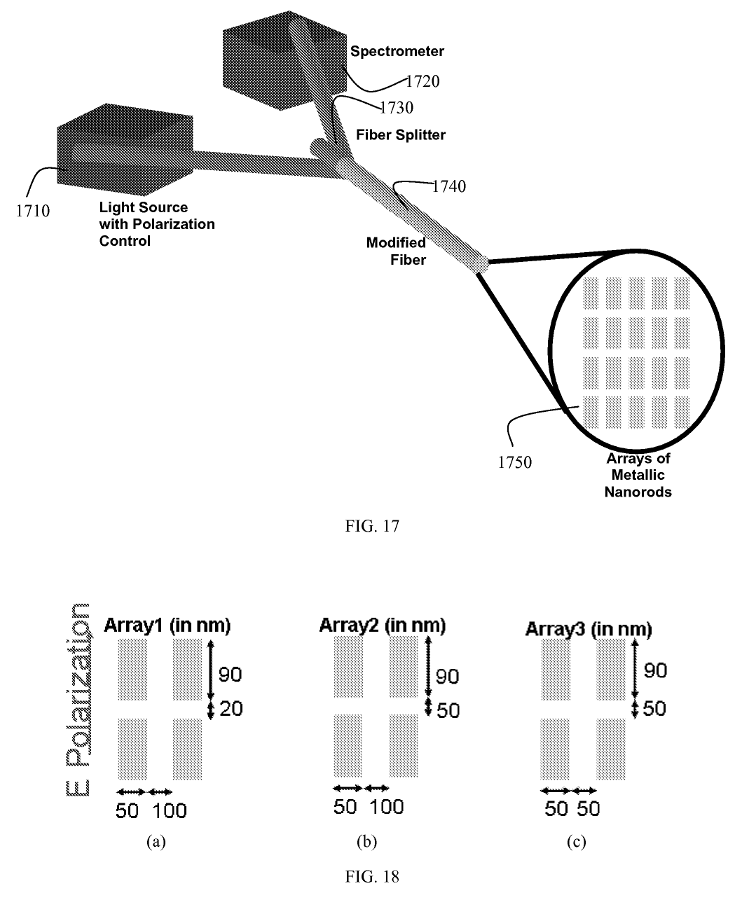

In another embodiment illustrated in FIG. 17, a new type of device comprises arrays of coupled metallic optical antennas fabricated onto the facet of an optical fiber. A light source with polarization control 1710 and a spectrometer 1720 are coupled to a fiber splitter 1730 which is further coupled to a modified fiber 1740. The modified fiber 1740 has arrays of metallic nanorods fabricated on the facet of the modified fiber. A suitably designed array enhances the near field of incident light in a particular wavelength range. Peak intensity enhancements can be of the order of 100. The peak enhancement of a given coupled array can be shifted by changing the media in between the gaps of the rods, lending itself to both Surface Enhanced Raman Scattering (SERS) measurements and sensing applications. The integration of coupled arrays on the facet of a fiber potentially provides a portable system that could be used for easy “probing” of various specimens and samples.

FIGS. 18(a)-(c) illustrate various examples of spacings of nanorod arrays in accordance with the present invention. The nanorods can be physically viewed as an LC circuit: ω²=1/LC. By increasing rod spacing along a direction parallel to the E field polarization, the capacitance between the two rods decreases, increasing the resonance frequency of the LC circuit, i.e., blue shift. By increasing rod spacing along a direction perpendicular to the E field polarization, the capacitance of neighboring coupled antennas increases due to increase of effective capacitor area leading to a lower resonant frequency, i.e., red shift.

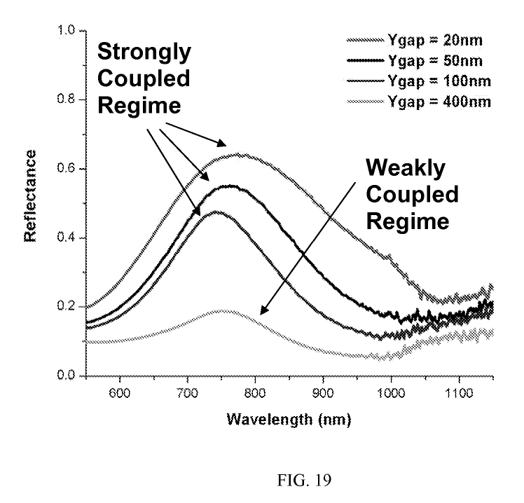

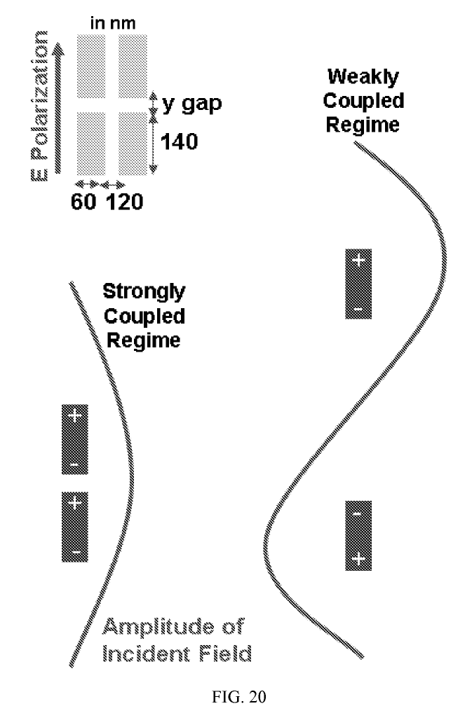

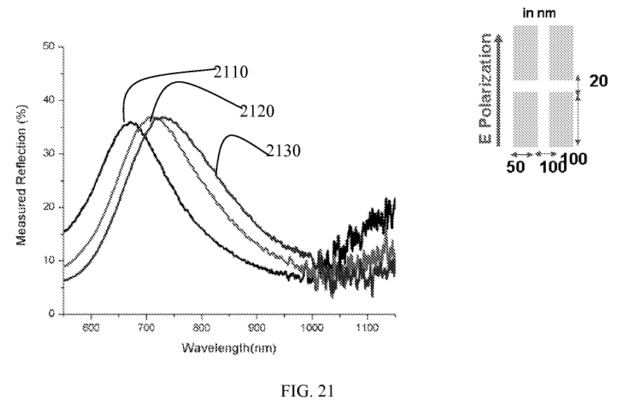

FIGS. 19-20 illustrate the red shift of weakly coupled arrays of gold optical antennas of the type illustrated in FIG. 17 constructed on a glass slide. The pitch between two adjacent rods is now close to the wavelength of the incident field so that a phase retardation occurs between the latter. This results in a decrease in the intra-rod electromagnetic field and a resonance at a longer wavelength. FIG. 21 illustrates a resonance red shift as the refractive index of surrounding media increases. In FIG. 21, 2110 illustrates rods in air, 2120 illustrates rods in 1.3 Index Fluid, and 2130 illustrates rods in 1.46 Index Fluid. Since the resonant length remains constant, the resonant wavelength increases as a result of the increase refractive index (fluid). Equivalently, as the refractive index between the rods increases, the capacitance also increases, decreasing the resonance frequency, i.e., red shift.

The arrays may be fabricated in a variety of ways. For example gold arrays may be fabricated on the facet of a fiber by creating the arrays with focused ion beam milling. Also, gold arrays may be fabricated on glass slides for easy optical characterization using electronic beam lithography.

Advantages of Optical Antennas Fabricated at End of an Optical Fiber

Here, the advantages of fabricating optical antennas at the ends of optical fibers are outlined.

(i). The optical antenna can be positioned in a location that is otherwise difficult to access, and the optical fiber provides an effective means of guiding light to it. Examples of such locations include high vacuum systems such as scanning electron microscopes and low temperature systems.

(ii). The optical antenna could be used with other types of lasers in addition to semiconductor lasers. These lasers could include gas lasers, solid state lasers and dye lasers. The advantage is that the laser need not be particularly compact.

(iii). Bundles of fibers could be used, with an optical antenna fabricated at the end of each fiber. By increasing the number of optical antennas in this way, the imaging throughput would be increased.

(iv). The optical antenna on the optical fiber could be used inside the human body for laser surgery, disease diagnosis through spectroscopy and local heating. In laser surgery, the intense optical fields could be used to cut and remove tissue. The optical antenna could also be used to enhance the spectroscopy (e.g. Raman) for disease diagnosis. The local heating of the optical antenna that occurs as a result of the finite conductivity of the metal could be used to heat tissue in the vicinity of the end of the optical fiber.

Optical Antenna Fabricated at End of Optical Fiber or Fiber Laser

It should be noted that the optical antenna can be fabricated onto the end of an optical fiber or at the end of a fiber laser. A fiber laser commonly may comprise an active fiber in which population inversion has been achieved among the ions embedded in the fiber (for example erbium), a pump laser and an optical cavity. An example of a fiber laser configuration is shown as FIG. 11, which illustrates a fiber laser 1100 designed to produce short optical pulses. The invention, however, is not restricted to that particular type of fiber laser. In FIG. 11, an optical fiber 1110 with a pump laser 1120 and an output 1140 at an end 1180 of the optical fiber is coupled via coupler 1130 to a phase modulator 1150, and undoped pulse shaping fiber 1160 and a doped amplifying fiber 1170. In another embodiment, the active optical antenna, or an array of active optical antennas may be placed on the facet of a fiber laser amplifier.

The advantage of the approach of the present invention is that the optical antenna is completely integrated with the laser source, without the need for additional intermediate optics to couple the laser to the optical antenna.

Microfluidic System with Integrated Optical Antennas

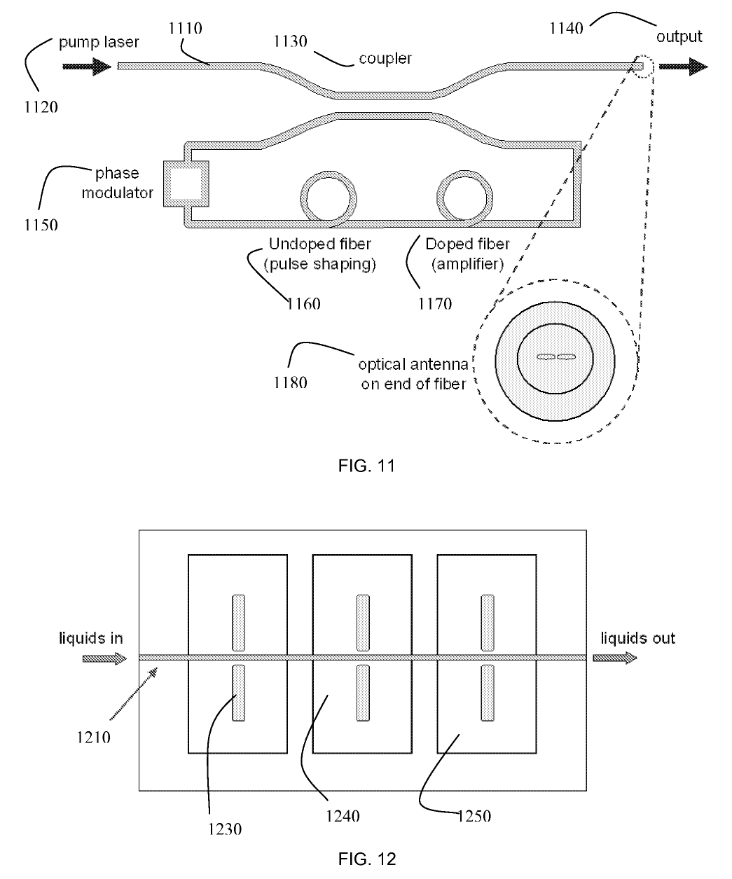

The ability of the optical antenna to generate intense and highly localized fields could be of great practical importance in microfluidic analysis systems. Optical antennas could be integrated with microfluidic analysis systems, as illustrated in FIG. 12. In this figure, a microfluidic channel 1210 drives the liquid under analysis through the antenna gaps. The antennas 1230, 1240, 1250 could be passive optical antennas or active optical antennas. In the active optical antenna case they would be fabricated onto the facets of semiconductor lasers coated with the appropriate passivation layer. In the illustrated system, intense and spatially confined fields are produced in the antenna gaps, and these fields illuminate the sample under study as it passes through the microfluidic channel. The molecules of interest in the sample could be tagged with fluorescent dye molecules. The operating wavelengths of the optical antennas would be set to match the excitation wavelengths of the fluorescent dye molecules. Therefore, when a tagged molecule flows through the gap of an antenna operating at the appropriate wavelength, the fluorescence of the dye is excited. The fluorescent emission is then be detected by collection optics (not shown in FIG. 12). The advantage of this scheme is the very large reduction in the optical excitation volume, compared to other approaches such as confocal microscopy. This has important practical advantages for the case of detecting molecules in very low concentrations, for example single molecules. One key problem in single molecule optical detection is low signal-to-background ratio. Due to the diffraction, in conventional techniques such as confocal microscopy the illuminated volume is ˜250 nm*250 nm*500 nm. The molecule may only have dimensions of nanometers or tens of nanometers. Therefore, the fluorescent signal from the single molecule is accompanied by a large background signal from fluorescence and Raman scattering from water and other molecules (e.g. impurities) in the illuminated volume. In the proposed device, the illumination volume is considerably smaller, thereby reducing the background signal.

It should be also noted that, in addition to fluorescence, other optical characterization methods are possible. These include Raman spectroscopy and optical absorption. Raman spectroscopy would benefit from the field enhancement provided by the optical antenna.

It should also be noted that the system could be used for analyzing the composition of gas samples, in addition to liquid samples. For example, it could be used to analyze the composition of exhaled breath.

The invention is not restricted to optical antennas operating at visible wavelengths. Mid-infrared wavelengths would be ideal for analysis of the composition of gas samples through absorption spectroscopy. In this case, the light source could be a quantum cascade laser (QCL). See F. Capasso. G. Gmachl, R. Paiella, A. Tredicucci, A. L. Hutchinson, D. L. Sivco, J. N. Baillargeon, A. Y. Cho, and H. C. Liu, New frontiers in quantum cascade lasers and applications, Special Millenium Issue of IEEE Journal of Selected Topics in Quantum Electronics 6, 931 (2001). The QCL has advantages in that it provides high powers across the mid infrared wavelength range and is a practical compact device. However, it should be realized that the invention is not restricted to the use of just this type of laser.

Optical Antennas in Illumination and Collection Modes

It should be noted that the optical antenna can be used in modes that we will term “illumination mode” and “collection mode”. In “illumination mode”, the optical antenna is illuminated, for example with a semiconductor laser or fiber laser, and the enhanced fields in the gap of the antenna are used for imaging, data storage, laser processing, etc. In “collection mode”, the optical antenna is used in applications such as very high spatial resolution microscopy of photonic devices. In this case, the antenna is scanned across the photonic device under study. The field distribution on the photonic device excites the surface plasmon of the optical antenna, which in turn radiates and is collected onto a photodetector. The optical antenna allows the field distribution in the photonic device to be measured with very high spatial resolution.

Measuring the Field Distributions in Optical Antennas

Measuring the field distributions in optical antennas is of great importance for their practical realization. A preferred embodiment of a method for carrying this out is outlined below. In this section we outline the approach. We begin by discussing the design of the antenna, and simulating its performance. We then present the method for measuring the field distribution in the optical antenna.

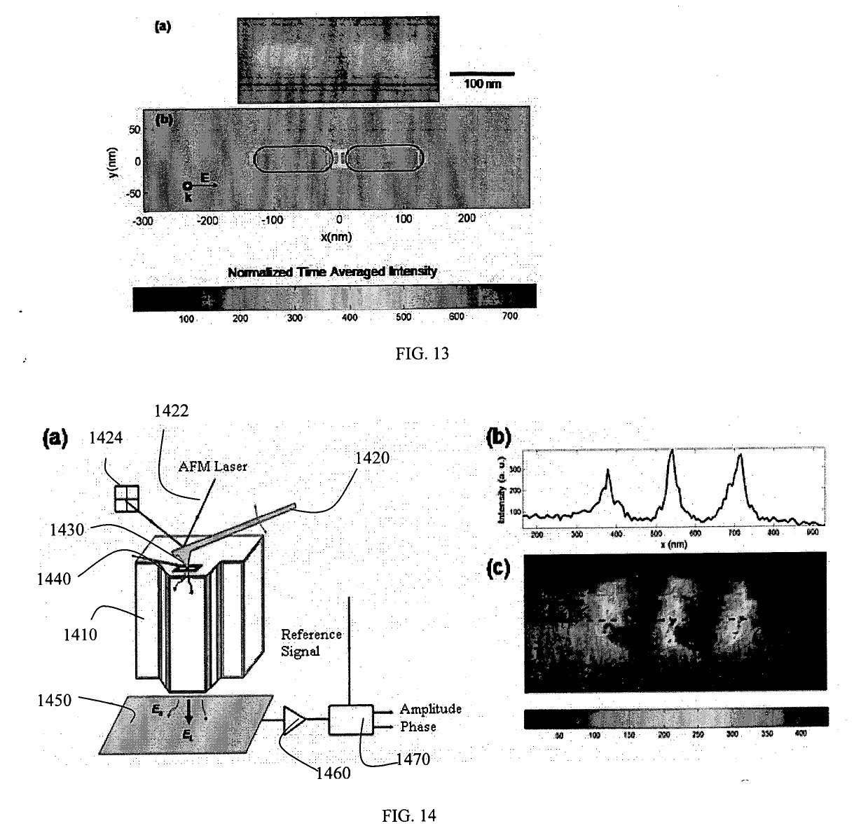

The optical antenna structure is fabricated on a commercial edge-emitting laser diode operating at a wavelength of 830 nm. To prevent electrical shorting of both the laser and the monitor photodiode of this commercial laser diode, Al2O3 was deposited first onto the facet as an insulating layer. A 100 nm thick Au layer was then evaporated onto the Al2O3 film. The nanoscale optical antenna was fabricated by focused ion beam milling (FIG. 13(a)).

First, finite difference time domain (FDTD) method simulations of the antenna structures are performed. The optical antenna consists of two gold rectangular sections separated by a gap of 20 nm. The rectangular gold sections are 120 nm long, 50 nm wide and 50 nm thick. The ends of the rectangles are realistically rounded, with radii of curvature of 25 nm. In simulations the incident field is polarized along the x-direction. The time averaged electric field intensity (<|E|²>) distribution for this polarization right above the antenna structure is shown in FIG. 13(b). The time averaged intensity in the gap is enhanced by a factor of 700 relative to the incident intensity. Physically this enhancement is due to the charges accumulating on both sides of the gap thus generating an intense electric field in the near field zone.

To measure these enhanced, primarily non-propagating fields near field optical measurements were performed. It has been shown that apertureless NSOM can be used to study the optical near-field of an aperture fabricated on a laser diode. See F. Chen, A. Itagi, J. A. Bain, D. D. Stancil, T. E. Schlesinger, L. Stebounova, G. C. Walker, and B. B. Akhremitchev, “Imaging of optical field confinement in ridge waveguides fabricated on very-small-aperture laser”, Appl. Phys. Lett. 83, 3245 (2003). The schematic of an example is shown in FIG. 14(a). The laser diode 1410 is driven by a constant current source (not shown). The gold-coated silicon atomic force microscope (AFM) tip 1420 is scanned over the optical antenna in non-contact mode via AFM laser 1422 and position sensitive photodetector 1424, with the very end of the tip scattering light from the field distribution on the surface of the optical antenna 1430. In general, light is scattered by the AFM tip 1420 in all directions. Some of the light is scattered back into the laser cavity 1440 and onto the monitor photodiode 1450 that collects light from the back facet of the laser diode. Note that the monitor photodiode 1450 only collects light from the back facet, since other parts of the photodiode 1450 were coated with gold during antenna fabrication. The photodetector current is pre-amplified 1460 and lock-in measurements 1470 are carried out at 1× and 2× the oscillation frequency of the AFM cantilever 1422. The measured optical near field distribution of the antenna structure with 2 f detection is shown in FIGS. 14(b) and 14(c). The size of the spot in the gap is about 30 nm in the x-direction. Although both our antenna structure and the C-aperture give comparable spot sizes, the antenna structure can confine higher optical near field intensities due to the capacitor like nature of the gap. As predicted by our simulations, we also observed intensity enhancement on the opposite ends of the structure.

In this work, we propose and demonstrate a new photonic device, the plasmonic laser antenna, which consists of a resonant optical antenna integrated on to the facet of a laser diode. Such a compact laser source with sub-wavelength spatial resolution provides distinct advantages in a number of applications including microscopy, spectroscopy, optical data storage, lithography and laser processing. It overcomes the problem of low optical power throughput of sub-wavelength apertures since our device relies only on the near-field enhancement around metallic nanoparticles, or nanoantennas, rather than on the enhanced transmission as in the case of an aperture in a sheet of metal.

FIGS. 2(a) and 1(a) are diagrams of a plasmonic laser antenna in accordance with two preferred embodiments of the present invention. FIG. 2(a) depicts a nanorod design while FIG. 1(a) depicts a design that would provide a stronger contrast between the intensity enhancement in the gap compared to the intensity enhancement at the ends of the antenna. A pair of coupled triangle-like particles (for example, a bowtie antenna) or of nanorods separated by a very small gap, which is less than 30 nm in this work, is defined on one of the facets of a diode laser. Gold nanorods can generate enhanced near fields through the excitation of surface plasmons. (See A. Bouhelier, R. Bachelot, G. Lerondel, S. Kostcheev, P. Royer, and G. P. Wiederrecht, Phys. Rev. Lett. 95, 267405 (2005)).

The large field enhancement in these structures, compared to gold nanospheres, is due to the substantially reduced plasmon dephasing rate, an effect caused by suppression of interband damping at near-infrared wavelengths. (See C. Sönnichsen, T. Franzl, T. Wilk, G. von Plessen, J. Feldmann, O. Wilson, and P. Mulvaney, Phys. Rev. Lett. 88, 077402 (2002).

In J. Aizpurua, Garnett W. Bryant, L. J. Richter, F. J. Garcia de Abajo, B. K. Kelley, and T. Mallouk, Phys. Rev. B 71, 235420 (2005), Aizpurua et al. carried out a numerical study of field enhancement with single and coupled nanorods. This work showed that in the latter a strongly localized intense optical spot in the nanoscale gap between the rods can be generated. This is due to capacitive coupling as the charges on the nanorod ends that define the gap have opposite signs. Hence, the enhanced field in the gap is mostly polarized along the length of the antenna. In the plasmonic device that we propose here, the size of the intense optical spot is largely determined by the size of the gap; a major advantage is that this scheme does not suffer from limited throughput as no subwavelength apertures are involved. With an aperture, the size of the optical spot can be equally small, but the power that can transmit through such a small subwavelength aperture will decay as the fourth power of the aperture diameter when the latter is smaller than one quarter of the illumination wavelength, similar to the lossy modes of a waveguide below cutoff.

Optical antennas were modeled on alumina substrate by Finite Difference Time Domain (FDTD) method calculations. The structures consist of two coupled gold nanorods separated by a 20 nm gap. This allowed us to determine the resonant antenna lengths for an excitation wavelength of 830 nm. Physically resonance is achieved when the length of each nanorod approximately equals an odd integer number of half surface plasmon wavelengths. The width and thickness of the nanorods are both 50 nm. The ends of the nanorods are rounded off, with a radius of curvature of 25 nm, similar to the fabricated structures. We used 0.188+5.39i for the complex refractive index of gold. Our simulations indicate that the first resonant length is ≈130 nm and the second one is ≈550 nm. The electric field intensity enhancements in the gap normalized to the incident intensity are ≈800 and ≈400 for the first and second resonance, respectively. These resonances are referred to as the first two dipole active modes, or as λ/2 and 3λ/2 antennas in antenna theory. (See C. A. Balanis, Antenna Theory, Analysis and Design, 3_{rd} edition, (Wiley, Hoboken, 2005)).

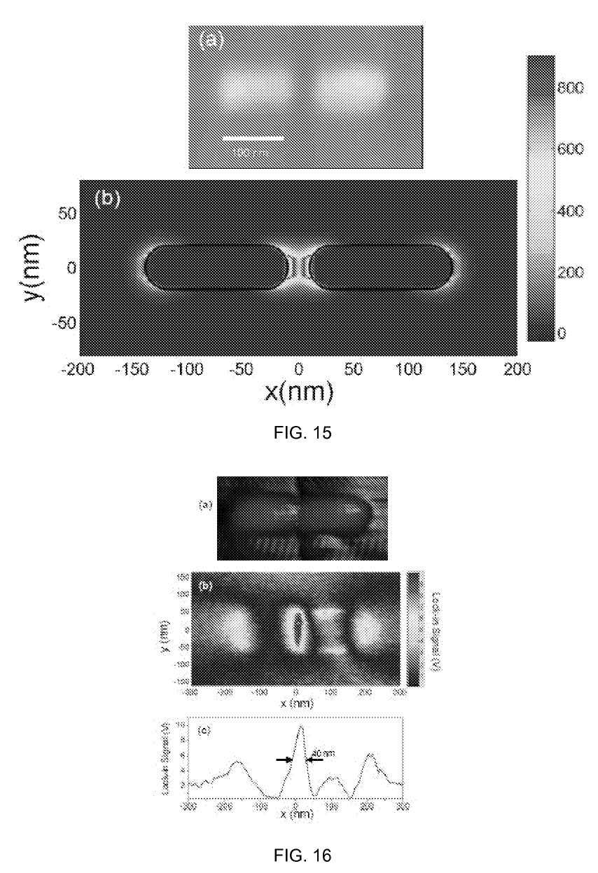

For the first resonance, the steady-state time-averaged total electric field intensity distribution around the optical antenna is shown in FIG. 15(b). Here the incident plane wave illumination is polarized along the antenna axis. We fabricated an optical antenna structure on a commercial edge-emitting laser diode (made by Sanyo Inc.) operating at a wavelength of 830 nm, which incorporates a photodiode to monitor the power from the back-facet. To prevent electrical shorting of the laser and the monitor photodiode in the laser package, Al₂O₃ was deposited first onto the laser facet as an insulating layer. After this step markers were etched by FIB patterning around the active region of the laser ridge. A gold layer was then evaporated onto the Al₂O₃ film. Next the optical antenna in FIG. 15(a) was defined by FIB milling. It consists of two gold nanorods separated by a gap of ≈30 nm. Each nanorod is ≈130 nm long, ≈50 nm wide and ≈50 nm thick.

We performed scanning near-field optical microscopy to measure the optical near-field distribution in the fabricated devices. It has been shown that apertureless near-field scanning optical microscopy (a-NSOM) can be used to study the optical near-field of an aperture fabricated on a laser diode (12). We employed an a-NSOM in a similar manner. (See F. Chen, A. Itagi, J. A. Bain, D. D. Stancil, T. E. Schlesinger, L. Stebounova, G. C. Walker, and B. B. Akhremitchev, Appl. Phys. Lett. 83, 3245 (2003)). In this technique, light is scattered by the end of a sharp atomic force microscope (AFM) tip. The AFM cantilever is driven at its resonant oscillation frequency, and the light scattered by the tip is collected by the back-facet photodiode. Lock-in detection is used to extract the component of the scattered light at the cantilever oscillation frequency and at its harmonics. The resulting signal gives an image of the optical near-field intensity. This can be understood by realizing that the signal at integer multiples of the cantilever oscillation frequency is produced by optical fields with which the tip is interacting. While the tip is in close proximity to the antenna gap, the evanescent fields excite surface plasmons in the tip, which in turn radiates a signal detected by the photodiode. When the tip is raised in the course of its oscillation, it no longer samples the evanescent field, so that no signal is generated. The gold-coated AFM tip can be modeled as a dipole interacting with its image in the underlying material. The non-linearity of this interaction means that the optical fields in close proximity to the surface will be scattered strongly at if, and also at higher integer frequencies (2f, 3f etc. . . . ). It has been shown that the higher harmonic (for example 2f) detection is more sensitive to the scattered flux modulated by the very end of the tip, rather than that scattered by the illuminated tip shaft and cantilever. However, in our experiments we found that the signal-to-noise ratio of 2f-images was lower than that of the 1f-images although they were qualitatively similar. Therefore only the latter are included in this article. The near-field imaging technique used here is sensitive to the light polarized along the height of the pyramidal AFM tip. In conventional AFMs the cantilever is mounted at a tilt and therefore scatters out a combination of all x, y, and z components of the electric field with weights that are difficult to determine. This makes a direct comparison between the simulations and the experiments difficult.

Our experimental setup is shown in FIG. 14a. The laser diode is driven by a pulsed current source since continuous wave (CW) operation caused the antennas to melt. Our lasers can emit up to 30 mW of power in CW mode, which is well above the damage threshold of gold. To minimize heating effects the laser was operated at a low duty cycle with a pulse length of 20 ns and a repetition frequency of 2 MHz. The plasmonic laser antenna device was mounted in a conventional atomic force microscope (PSIA XE-120). In order to improve their scattering efficiency, silicon AFM tips (made by Budgetsensors Inc.) were coated with <5 nm Ti layer followed by ˜30 nm thick Au, using electron-beam evaporation. This metallized AFM tip is then used in non-contact mode with the surface, where it is modulated at ˜300 kHz while the sample is scanned underneath it. While mapping out the topography in this typical AFM manner, we also measure the optical near-field intensity distribution. Light is scattered by the metallized AFM tip; while this radiation reaches the monitor photodiode predominantly back through the laser diode, a fraction of it is also collected by repeated scattering off the cantilever. The signal from the photodiode is then amplified and fed into a lock-in amplifier where a phase sensitive measurement is performed using as a reference the frequency of the AFM cantilever.

FIG. 16 shows the results of our measurements. The full-width-at-half-maximum of the central peak of the near-field intensity distribution is 40 nm in the x-direction and 100 nm in the y-direction (FIG. 16(b)-(c)). This intense optical spot is localized within an area that is 50 times smaller than what one would obtain with conventional optics such as lenses (Rayleigh limit) in addition to the large intensity enhancement, as calculated from our simulations. Such resonant enhancements in the gap are possible only if the incident light is polarized along the antenna structures, hence the antennas are oriented parallel to the active layers of our diode laser, since its emission is TE-polarized. We also tested antenna structures with the same parameters, but rotated by 90°, that is with the incident light polarized perpendicular to the antenna axis. No intensity enhancement was observed in the gap in these structures, in agreement with the resonant polarization-sensitive nature of resonant optical antennas.

The fabricated antenna (FIG. 15(a)) exhibits also field enhancement on the far ends of the nanorods (FIG. 16(b)-(c)) as predicted by our simulations. For some applications such as optical data storage where a single optical spot is desired, these multiple spatial peaks around the structure could be problematic. This can be overcome by employing a bowtie design (FIG. 1(a)) since the tapering in the latter produces a “lighting rod” effect so that the fields will be mostly confined in the gap region. The small bump seen in the AFM image of FIG. 16(a), below the right-hand side nanorod is most likely due to nanomasking during FIB patterning, which causes stray near fields in FIG. 16(b)-(c). It is likely that the composition of this bump has changed due to doping by Ga ions used in our FIB system and this may be the reason why the near-field is perturbed strongly as if this bump acts like a metallic nanoparticle. Since we can only measure the relative near field intensity but not its magnitude, we can only provide an estimate of the actual near field intensity. Using a large area photodetector placed in the far field we measured an average output power of 0.3 mW for the same operating conditions under which the data shown in FIG. 17 were taken. Based on the simulated intensity enhancement of 800, the above optical power leads to a peak intensity≈1 GW/cm₂ in the gap. This corresponds to an electric field of 10⁵ V/cm at 10 nm above the surface, where the total intensity drops to 20% of its value right on the antenna surface. Such large localized optical intensities are very important for single molecule SERS.

In summary, we have demonstrated a new surface plasmon device, the plasmonic laser antenna, that generates intense and highly confined optical fields. We want to stress that resonant optical antennas can be defined on semiconductor lasers emitting in the visible, near-, mid- and far-infrared spectrum, thus including both diode lasers and quantum cascade lasers. We expect that plasmonic laser antennas will be useful in a broad range of applications including optical data storage₂₅ at densities exceeding 1 Tb/inch₂, orders of magnitude higher than the current highest density digital versatile disks (DVDs), near field optical microscopy and spectroscopy, heat-assisted magnetic recording, nanoscale optical lithography as well as spatially resolved chemical imaging and spectroscopy.

The foregoing description of the preferred embodiment of the invention has been presented for purposes of illustration and description. It is not intended to be exhaustive or to limit the invention to the precise form disclosed, and modifications and variations are possible in light of the above teachings or may be acquired from practice of the invention. The embodiment was chosen and described in order to explain the principles of the invention and its practical application to enable one skilled in the art to utilize the invention in various embodiments as are suited to the particular use contemplated. It is intended that the scope of the invention be defined by the claims appended hereto, and their equivalents. The entirety of each of the aforementioned documents is incorporated by reference herein.

1. A semiconductor laser apparatus comprising:
an active region;
a laser facet; and
an optical antenna on said laser facet.

2. A semiconductor laser apparatus according to claim 1 wherein said optical antenna comprises a bow tie antenna.

3. A semiconductor laser apparatus according to claim 1 wherein said optical antenna comprises a cross optical antenna.

4. A semiconductor laser apparatus according to claim 1 wherein said optical antenna comprises a dipole optical antenna.

5. A semiconductor laser apparatus according to claim 1 wherein said optical antenna comprises a metal coating having an opening therein.

6. A semiconductor laser apparatus according to claim 5 wherein said optical antenna comprises a dipolar optical antenna formed in said opening.

7. A semiconductor laser apparatus according to claim 5 wherein said optical antenna comprises a cross antenna formed in said opening.

8. A semiconductor laser apparatus according to claim 1 wherein said laser apparatus comprises a diode laser.

9. A laser apparatus according to claim 1 wherein said laser apparatus comprises a quantum cascade laser.

10. A laser apparatus according to claim 1 wherein said optical antenna comprises an array of optical antennas.

11. A semiconductor laser apparatus comprising:
an active region;
a facet; and
a metallic structure integrated on the facet of said semiconductor laser, said metallic structure comprising metallic elements functioning as antennas at optical wavelengths by spatially concentrating laser radiation of wavelength in the near field zone.

12. A semiconductor laser apparatus according to claim 11 wherein said metallic structure comprises a bow tie antenna.

13. A semiconductor laser apparatus according to claim 11 wherein said metallic structure comprises a cross optical antenna.

14. A semiconductor laser apparatus according to claim 11 wherein said metallic structure comprises a dipolar optical antenna.

15. A laser apparatus according to claim 11 wherein said metallic structure comprises a metal coating having an opening therein.

16. A laser apparatus according to claim 15 wherein said optical antenna comprises a dipolar optical antenna formed in said opening.

17. A laser apparatus according to claim 15 wherein said optical antenna comprises a cross antenna formed in said opening.

18. A laser apparatus according to claim 11 wherein said metallic structure comprises an array of optical antennas.

19. A laser apparatus comprising:
a laser;
an optical fiber coupled to said laser, said optical fiber having a facet; and
an optical antenna on said facet of said optical fiber.

20. A laser apparatus according to claim 19 wherein said optical antenna comprises an array of metallic nanorods.

21. A laser apparatus according to claim 19 wherein said optical antenna comprises a bowtie antenna.

22. A laser apparatus according to claim 19 wherein said optical antenna comprises cross optical antenna.

23. A laser apparatus according to claim 19 wherein said optical antenna comprises a dipole optical antenna.

24. A laser apparatus according to claim 19 wherein said optical antenna comprises a metal coating having an opening therein.

25. A laser apparatus according to claim 19 wherein said optical antenna comprises a dipolar optical antenna formed in said opening.

26. A laser apparatus according to claim 19 wherein said optical antenna comprises a cross antenna formed in said opening.

27. A laser apparatus according to claim 19 wherein said optical antenna comprises an array of optical antennas.

28. A laser apparatus comprising:
a fiber laser having a facet; and
an optical antenna on said facet of said fiber laser.

29. A laser apparatus according to claim 28 wherein said optical antenna comprises an array of optical antennas.

30. A laser apparatus comprising:
a fiber laser amplifier having a facet; and
an optical antenna on said facet of said fiber laser amplifier.

31. A laser apparatus according to claim 30 wherein said optical antenna comprises an array of optical antennas.

32. A laser apparatus according to claim 30, wherein said fiber laser amplifier comprises an Erbium-doped fiber laser amplifier.

33. A microfluidic analysis system comprising:
a plurality of active optical antennas;
a gap between at least two of said plurality of active optical antennas;
a microfluidic channel extending through said gap;
means for driving a sample through said microfluidic channel; and
means for detecting a fluorescent emission from said sample.
